(19) United States
(12) Patent Application Publication
(10) Pub. No.: US 2020/0358251 A1
(43) Pub. Date: Nov. 12, 2020

(54) SURFACE-EMITTING LASER, ELECTRONIC DEVICE, AND METHOD OF MANUFACTURING SURFACE-EMITTING LASER

(71) Applicant: SUMITOMO ELECTRIC INDUSTRIES, LTD., Osaka (JP)

(72) Inventor: Yukihiro TSUJI, Osaka-shi (JP)

(73) Assignee: SUMITOMO ELECTRIC INDUSTRIES, LTD., Osaka (JP)

(21) Appl. No.: 16/856,261

(22) Filed: Apr. 23, 2020

(30) Foreign Application Priority Data
May 8, 2019 (JP) 2019-088615

(51) Int. Cl. H01S 5/183; H01S 5/042

(52) U.S. Cl. CPC H01S 5/18308; H01S 5/18361; H01S 5/0425

(57) ABSTRACT

A surface-emitting laser includes a light-emitting portion provided on a substrate; and two first electrodes and a second electrode provided over the substrate. At least one of the two first electrodes and the second electrode are electrically connected to the light-emitting portion. The at least one of the two first electrodes is one of a cathode electrode and an anode electrode. The second electrode is the other of the cathode electrode and the anode electrode. One of the two first electrodes and the second electrode are arranged in a first direction. The other of the two first electrodes and the second electrode are arranged in a second direction intersecting the first direction.

### CROSS-REFERENCE TO RELATED APPLICATION

This application is based upon and claims the benefit of priority of the prior Japanese Patent Application No. 2019-088615, filed on May 8, 2019, the entire contents of which are incorporated herein by reference.

### FIELD

The present disclosure relates to a surface-emitting laser, an electronic device, and a method of manufacturing a surface-emitting laser.

### BACKGROUND

PCT Publication No. WO 2015/033649 (Patent Document 1) discloses a vertical cavity surface-emitting laser (VCSEL). A chip-on-board method in which a chip on which a VCSEL is formed is mounted on, for example, a printed circuit board may be used.

### SUMMARY

Preferably, the positions of the anode and cathode electrodes of the VCSEL correspond to the positions of the electrodes on the printed circuit board. That is, the anode electrode of the VCSEL is disposed in the vicinity of the anode electrode of the printed circuit board, and the cathode electrode of the VCSEL is disposed in the vicinity of the cathode electrode of the printed circuit board. However, the electrode arrangements of printed circuit boards vary. Therefore, a plurality of types of VCSEL in which electrodes are arranged differently may be manufactured in accordance with the designs of printed circuit boards. As a result, the cost increases. It is therefore an object of the present invention to provide a surface-emitting laser, an electronic device, and a method of manufacturing a surface-emitting laser that allow for cost reduction.

A surface-emitting laser according to an aspect of the present invention includes a light-emitting portion provided on a substrate, and two first electrodes and a second electrode provided over the substrate, wherein at least one of the two first electrodes and the second electrode are electrically connected to the light-emitting portion, the at least one of the two first electrodes is one of a cathode electrode and an anode electrode, the second electrode is the other of the cathode electrode and the anode electrode, one of the two first electrodes and the second electrode are arranged in a first direction, and the other of the two first electrodes and the second electrode are arranged in a second direction intersecting the first direction.

An electronic device according to another aspect of the present invention includes a mounting substrate and a surface-emitting laser mounted on the mounting substrate, the surface-emitting laser having a light-emitting portion provided on a substrate and two first electrodes and a second electrode provided over the substrate, at least one of the two first electrodes and the second electrode being electrically connected to the light-emitting portion, the at least one of the two first electrodes being one of a cathode electrode and an anode electrode, the second electrode being the other of the cathode electrode and the anode electrode, one of the two first electrodes and the second electrode being arranged in a first direction, the other of the two first electrodes and the second electrode being arranged in a second direction intersecting the first direction, the mounting substrate having a first pad and a second pad, the first pad being opposed to one of the two first electrodes and being electrically connected to the one of the two first electrodes using a first bonding wire and not electrically connected to the other of the two first electrodes, the second pad being opposed to the second electrode and being electrically connected to the second electrode using a second bonding wire.

A method of manufacturing a surface-emitting laser according to another aspect of the present invention includes the steps of forming a light-emitting portion on a substrate; and forming two first electrodes and a second electrode over the substrate, wherein at least one of the two first electrodes and the second electrode are electrically connected to the light-emitting portion, the at least one of the two first electrodes is one of a cathode electrode and an anode electrode, the second electrode is the other of the cathode electrode and the anode electrode, one of the two first electrodes and the second electrode are arranged in a first direction, and the other of the two first electrodes and the second electrode are arranged in a second direction intersecting the first direction.

### BRIEF DESCRIPTION OF THE DRAWINGS

FIG. 1A is a plan view illustrating a surface-emitting laser according to a first embodiment.

FIG. 1B is a cross-sectional view illustrating the surface-emitting laser.

FIGS. 2A and 2B are plan views illustrating electronic devices.

FIGS. 3A and 3B are plan views illustrating a method of manufacturing the surface-emitting laser.

FIGS. 4A and 4B are plan views illustrating the method of manufacturing the surface-emitting laser.

FIGS. 5A and 5B are plan views illustrating the method of manufacturing the surface-emitting laser.

FIGS. 6A and 6B are plan views illustrating the method of manufacturing the surface-emitting laser.

FIGS. 7A and 7B are plan views illustrating the method of manufacturing the surface-emitting laser.

FIGS. 8A and 8B are plan views illustrating the method of manufacturing the surface-emitting laser.

FIGS. 9A and 9B are plan views illustrating the method of manufacturing the surface-emitting laser.

FIGS. 10A and 10B are plan views illustrating the method of manufacturing the surface-emitting laser.

FIG. 11 is a plan view illustrating a surface-emitting laser according to a modification of the first embodiment.

FIG. 12A is a plan view illustrating a surface-emitting laser according to Comparative Example 1.

FIG. 12B is a plan view illustrating a surface-emitting laser according to Comparative Example 2.

FIGS. 13A and 13B are plan views illustrating electronic devices according to a second embodiment.

### DESCRIPTION OF EMBODIMENTS

Some embodiments will now be described.

(1) An embodiment of the present disclosure is a surface-emitting laser comprising a light-emitting portion provided on a substrate, and two first electrodes and a second electrode provided over the substrate, wherein at least one of the two first electrodes and the second electrode are electrically connected to the light-emitting portion, the at least one of the two first electrodes is one of a cathode electrode and an anode electrode, the second electrode is the other of the cathode electrode and the anode electrode, one of the two first electrodes and the second electrode are arranged in a first direction, and the other of the two first electrodes and the second electrode are arranged in a second direction intersecting the first direction. Since the two first electrodes are provided, the arrangement of the first electrodes and the second electrode can be changed by changing the orientation of the surface-emitting laser. Since it is not necessary to manufacture a plurality of types of surface-emitting lasers having different electrode arrangements, cost can be reduced.

(2) The substrate may have a rectangular shape, the two first electrodes may be opposed to two of four corners of the substrate, the second electrode may be opposed to one of the four corners, one of the two first electrodes and the second electrode may be arranged along a first side of the substrate, and the other of the two first electrodes and the second electrode may be arranged along a second side of the substrate adjacent to the first side. By rotating the rectangular surface-emitting laser, the arrangement of the first electrodes and the second electrode can be changed. Therefore, the cost of the surface-emitting laser can be reduced.

(3) One of the two first electrodes may be electrically connected to the light-emitting portion, and the other may not be connected to the light-emitting portion. If one of the two first electrodes is not connected, an increase in parasitic capacitance can be suppressed.

(4) The light-emitting portion may include a lower reflector layer provided on the substrate, an active layer provided on the lower reflector layer, and an upper reflector layer provided on the active layer, wherein the first electrodes and the second electrode may be located above the upper reflector layer, the at least one of the two first electrodes may be electrically connected to the lower reflector layer, and the second electrode may be electrically connected to the upper reflector layer. It is possible to suppress an increase in parasitic capacitance generated between the first electrodes and the lower reflector layer.

(5) Another embodiment of the present disclosure is an electronic device including a mounting substrate and a surface-emitting laser mounted on the mounting substrate. The surface-emitting laser has a light-emitting portion provided on a substrate and two first electrodes and a second electrode provided over the substrate. At least one of the two first electrodes and the second electrode are electrically connected to the light-emitting portion, the at least one of the two first electrodes being one of a cathode electrode and an anode electrode. The second electrode is the other of the cathode electrode and the anode electrode. One of the two first electrodes and the second electrode is arranged in a first direction. The other of the two first electrodes and the second electrode is arranged in a second direction intersecting the first direction. The mounting substrate has a first pad and a second pad. The first pad is opposed to one of the two first electrodes and is electrically connected to the one of the two first electrodes using a first bonding wire and not electrically connected to the other of the two first electrodes. The second pad is opposed to the second electrode and being electrically connected to the second electrode using a second bonding wire.

(6) Another embodiment of the present disclosure is a method of manufacturing a surface-emitting laser, comprising the steps of forming a light-emitting portion on a substrate; and forming two first electrodes and a second electrode over the substrate, wherein at least one of the two first electrodes and the second electrode are electrically connected to the light-emitting portion, the at least one of the two first electrodes is one of a cathode electrode and an anode electrode, the second electrode is the other of the cathode electrode and the anode electrode, one of the two first electrodes and the second electrode are arranged in a first direction, and the other of the two first electrodes and the second electrode are arranged in a second direction intersecting the first direction. Since it is not necessary to manufacture a plurality of types of surface-emitting lasers having different electrode arrangements, cost can be reduced.

(7) The first electrodes and the second electrode may include a first metal layer and a second metal layer, and the step of forming the first electrodes and the second electrode may include the substeps of forming a first resist and a first mask in order over the substrate and patterning the first resist using the first mask; forming the first metal layer over the first resist; forming a second resist and a second mask in order on the first metal layer and patterning the second resist using the second mask; and forming the second metal layer on the second resist and the first metal layer. Since the number of types of masks can be reduced as compared with the case of manufacturing a plurality of types of surface-emitting lasers, the cost can be reduced.

(8) The method may further include the steps of forming a third electrode and a fourth electrode electrically connected to the light-emitting portion; forming a first insulating film over the substrate, the third electrode, and the fourth electrode; forming a third resist and a third mask on the first insulating film in order and patterning the third resist using the third mask; and etching the first insulating film using the third resist to form a first opening through which the third electrode is exposed and a second opening through which the fourth electrode is exposed in the first insulating film, wherein the step of forming the first electrodes and the second electrode may be performed after the step of forming the first opening and the second opening in the first insulating film, one of the two first electrodes may be electrically connected to the third electrode through the first opening, the other of the two first electrodes may not be electrically connected to the third electrode, and the second electrode may be electrically connected to the fourth electrode through the second opening. Since the number of types of masks can be reduced as compared with the case of manufacturing a plurality of types of surface-emitting lasers, the cost can be reduced.

(9) The method may further include the steps of forming a second insulating film over the substrate, the first electrodes, and the second electrode; forming a fourth resist and a fourth mask in order on the second insulating film and patterning the fourth resist using the fourth mask; and etching the second insulating film using the fourth resist to form a third opening through which one of the first electrodes is exposed and a fourth opening through which the second electrode is exposed in the second insulating film. Since the number of types of masks can be reduced as compared with the case of manufacturing a plurality of types of surface-emitting lasers, the cost can be reduced.

Specific examples of surface-emitting lasers, electronic devices, and methods of manufacturing surface-emitting lasers according to embodiments of the present invention will be described below with reference to the drawings. It should be noted that the present invention is not limited to these examples, but is indicated by the claims, and it is intended to include all modifications within the meaning and range of equivalency of the claims.

### First Embodiment

(Surface-Emitting Laser)

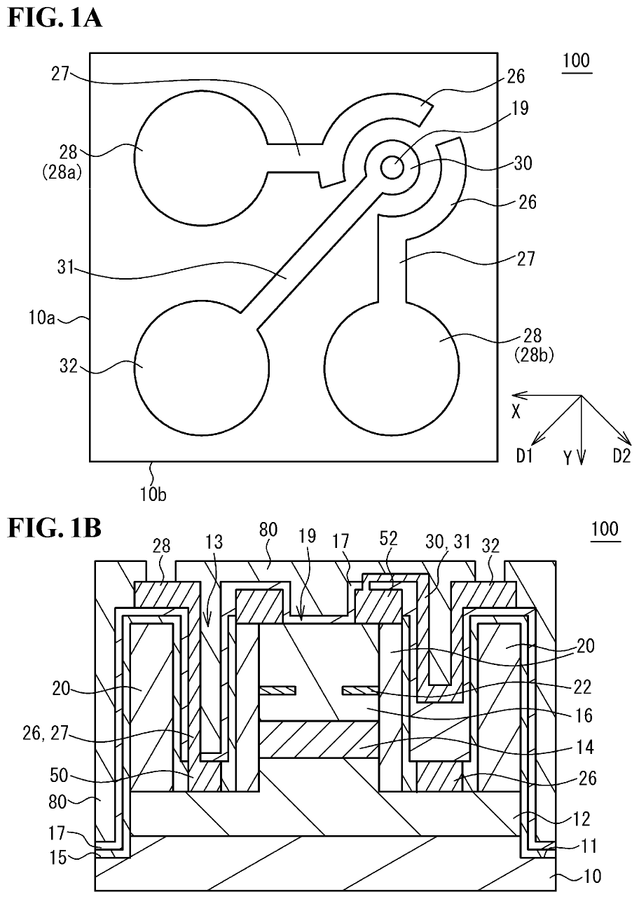

FIG. 1A is a plan view illustrating a surface-emitting laser 100 according to a first embodiment, and FIG. 1B is a cross-sectional view illustrating the surface-emitting laser 100.

As illustrated in FIG. 1A and FIG. 1B, the surface-emitting laser 100 has a rectangular planar shape and includes a mesa 19 and pads 28 and 32. The X-axis and the Y-axis in FIG. 1A are orthogonal to each other, and the sides of the surface-emitting laser 100 extend in the X-axis direction or the Y-axis direction. One of the sides extending in the Y-axis direction is referred to as “side 10a”, and one of the sides extending in the X-axis direction is referred to as “side 10b”. The D1 axis is located in the XY plane and between the X-axis direction and the Y-axis direction, and the D2 axis is orthogonal to the D1 axis. The D1 axis direction and the D2 axis direction are diagonal directions of the surface-emitting laser 100.

The mesa 19, the two pads 28 (first electrodes), and the pad 32 (second electrode) are disposed so as to be opposed to three of the four corners of the surface-emitting laser 100. One of the two pads 28 (pad 28a) is positioned away from the mesa 19 in the X-axis direction, the other pad 28b is positioned away from the mesa 19 in the Y-axis direction, and the pad 32 is positioned away from the mesa 19 in one of the two diagonal directions (D1 axis direction). The pad 28a and 32 are arranged along the side 10a (first side) of a substrate 10. The pad 28b and the pad 32 are arranged along the side 10b (second side). The pad 28a and the pad 28b are opposed to each other in one of the two diagonal directions (D2-axis direction). The pad 32 is positioned between the pads 28a and 28b on the X side and the Y side.

The mesa 19 functions as a light-emitting portion. An electrode 30 is provided on the mesa 19, a groove 13 is provided around the mesa 19, and two electrodes 26 are provided in the groove 13. Each of the pads 28a and 28b is electrically connected to one of the electrodes 26 by wiring 27. The pad 32 is electrically connected to the electrode 30 by wiring 31. The pads 28 function as a cathode electrode, and the pad 32 functions as an anode electrode. The pad 32 is electrically connected to the compound semiconductor of the mesa 19. The two electrodes 26 are spaced apart and are not electrically connected with each other. One of the two pads 28 is electrically connected through the corresponding electrode 26 to the compound semiconductor of the mesa 19, and the other is not connected to the compound semiconductor.

The length of one side of the surface-emitting laser 100 is, for example, 200 μm, the diameter of the pads 28a, 28b, and 32 is, for example, 60 μm, and the distance between the outer edges (outer peripheral surfaces) of the two electrodes 26 is, for example, 70 μm.

As illustrated in FIG. 1B, the surface-emitting laser 100 is a VCSEL including the substrate 10, a lower reflector (distributed Bragg reflector (DBR)) layer 12, an active layer 14, an upper reflector layer 16, and the electrodes 26 and 28.

The substrate 10 is, for example, a semi-insulating gallium arsenide (GaAs) semiconductor substrate. The lower reflector layer 12, the active layer 14, and the upper reflector layer 16 are sequentially stacked on the substrate 10, and these semiconductor layers form the mesa 19.

The lower reflector layer 12 is, for example, a semiconductor multilayered film in which n-type Al_{0.16}Ga_{0.84}As layers and Al_{0.9}Ga_{0.1}As layers are alternately stacked, each with an optical thickness of λ/4. Note that λ is the wavelength of light. The lower reflector layer 12 is doped with, for example, silicon (Si). The lower reflector layer 12 includes a conductive contact layer in contact with an electrode 50, and the contact layer is formed of, for example, AlGaAs.

The active layer 14 is formed of, for example, AlGaAs and AlInGaAs, has a multiple quantum well (MQW) structure in which quantum well layers and barrier layers are alternately stacked, and has an optical gain. Cladding layers (not illustrated) are interposed between the active layer 14 and the lower reflector layer 12, and between the active layer 14 and the upper reflector layer 16.

The upper reflector layer 16 is, for example, a semiconductor multilayered film in which p-type Al_{0.16}Ga_{0.84}As layers and Al_{0.9}Ga_{0.1}As layers are alternately stacked, each with an optical thickness of λ/4. The upper reflector layer 16 is doped with carbon (C), for example. The upper reflector layer 16 includes a conductive contact layer in contact with an electrode 52, and the contact layer is formed of, for example, AlGaAs.

The substrate 10, the lower reflector layer 12, the active layer 14, and the upper reflector layer 16 may be formed of other compound semiconductors. For example, the substrate 10 may be made of AlₓGa₁₋ₓAs (0≤x≤0.2) instead of GaAs. The substrate 10 contains Ga and As.

A current confinement layer 22 is formed by selectively oxidizing a part of the upper reflector layer 16. The current confinement layer 22 is formed at the periphery of the upper reflector layer 16, and is not formed at the center of the upper reflector layer 16. The current confinement layer 22 contains, for example, aluminum oxide (Al₂O₃) and is insulating, and a current is less likely to flow through the current confinement layer 22 than through the non-oxidized portion. Therefore, the unoxidized portion on the center side of the upper reflector layer 16 becomes a current path, and efficient current injection becomes possible.

A high-resistance region 20 is formed on the outer side of the current confinement layer 22 and on the peripheral portion of the mesa 19. The high-resistance region 20 extends over the upper reflector layer 16, the active layer 14, and a portion of the upper side of the lower reflector layer 12, and is formed by, for example, implanting ions such as protons. The groove 13 extends through the high-resistance region 20 in the thickness direction, reaches the lower reflector layer 12, and surrounds the mesa 19. A groove 11 is located outside the groove 13 and the high-resistance region 20, surrounds them, and reaches the substrate 10 in the thickness direction.

An insulating film 15 is, for example, a silicon nitride (SiN) film having a thickness of 40 nm, and covers the bottom surface of the groove 11, the surface of the high-resistance region 20, and the surface of the mesa 19. An insulating film 17 is, for example, a SiN film, and covers the insulating film 15. An insulating film 80 is, for example, a SiN film, and covers the insulating film 17. The insulating films 15 and 17 function as reflective films for reflecting light emitted from the active layer 14, and the thickness and the refractive index are determined so as to increase the reflectance.

The electrode 50 is, for example, an n-type electrode having a stacked structure of gold-germanium (AuGe) and nickel (Ni) layers, and is provided on the inner side of the groove 13 and on the surface of the lower reflector layer 12. The electrode 52 is, for example, a p-type electrode having a stacked structure of titanium (Ti), platinum (Pt), and Au layers, and is provided on the mesa 19 and on the surface of the upper reflector layer 16. The electrodes 50 and 52 are ohmic electrodes. The pads 28 and 32 are located above the upper reflector layer 16. The electrodes 26, the wiring 27, and the pads 28 are electrically connected to the electrode 50 and the lower reflector layer 12 through an opening of the insulating film 17. The electrode 30, the wiring 31, and the pad 32 are electrically connected to the electrode 52 and the upper reflector layer 16. The electrodes 26 and 30, the wiring 27 and 31, and the pads 28 and 32 include a seed metal and a plating layer as described later.

(Electronic Device)

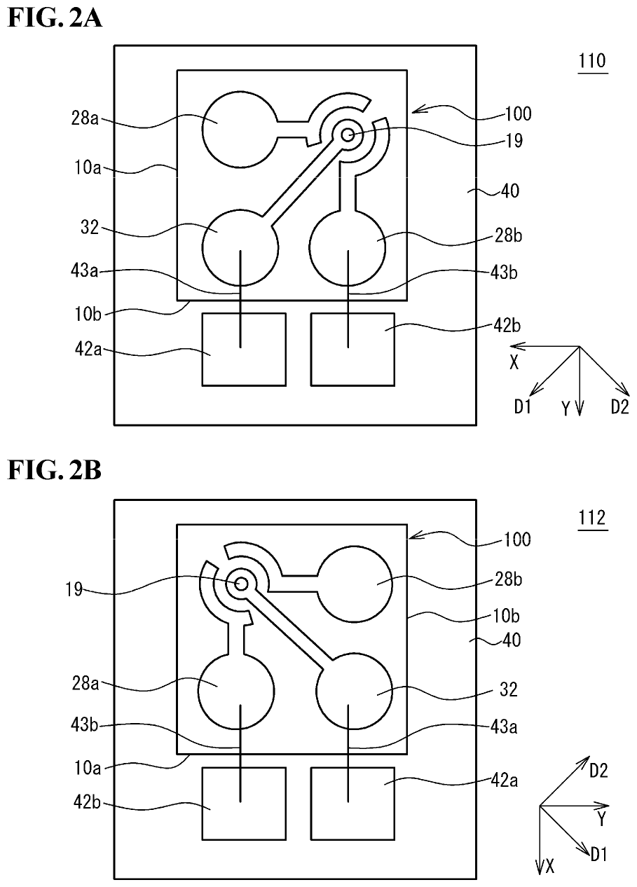

FIG. 2A and FIG. 2B are plan views illustrating electronic devices. An electronic device 110 illustrates in FIG. 2A and an electronic device 112 illustrates in FIG. 2B include a printed circuit board 40 and the surface-emitting laser 100 mounted on the printed circuit board 40. Pads 42a and 42b (first and second pads) are provided on the surface of the printed circuit board 40. The orientation of the surface-emitting laser 100 and the positions of the pads 42a and 42b in the electronic device 110 of FIG. 2A are different from the orientation of the surface-emitting laser 100 and the positions of the pads 42a and 42b in the electronic device 112 of FIG. 2B.

As illustrated in FIG. 2A, on the printed circuit board 40 of the electronic device 110, the pad 42b, serving as a cathode electrode, and the pad 42a, serving as an anode electrode, are arranged in order from the right to the left of the figure (from the −X side to the +X side). The surface-emitting laser 100 is mounted on the printed circuit board 40 so that the side 10b of the surface-emitting laser 100 faces the pads 42a and 42b. The pad 42b of the printed circuit board 40 and the pad 28b, which is the cathode electrode of the surface-emitting laser 100, face each other in the Y-axis direction, and are electrically connected to each other by a bonding wire 43b (first bonding wire). The pad 42a and the pad 32, which is the anode electrode of the surface-emitting laser 100, face each other in the Y-axis direction, and are electrically connected to each other by a bonding wire 43a (second bonding wire).

As illustrated in FIG. 2B, on the printed circuit board 40 of the electronic device 112, the pads 42a and 42b are arranged in order from the right to the left of the figure (from the +Y side to the −Y side). Further, the surface-emitting laser 100 is rotated by 90 degrees to the left in the XY plane as compared with the electronic device 110. That is, the surface-emitting laser 100 is mounted on the printed circuit board 40 so that the side 10a of the surface-emitting laser 100 faces the pads 42a and 42b. The pad 42b and the pad 28a face each other in the Y-axis direction, and are electrically connected to each other by the bonding wire 43b. The pad 42a and the pad 32 face each other in the Y-axis direction and are electrically connected to each other by the bonding wire 43a.

As described above, the orientation of the surface-emitting laser 100 is changed in accordance with the arrangement of the pads on the printed circuit board 40. Thus, the pad 32, serving as the anode electrode, and the pad 42a can be opposed to each other, and the pad 28a or 28b, serving as the cathode electrode, and the pad 42b can be opposed to each other. As a result, the pads can be connected to each other without crossing the bonding wires 43a and 43b.

(Manufacturing Method)

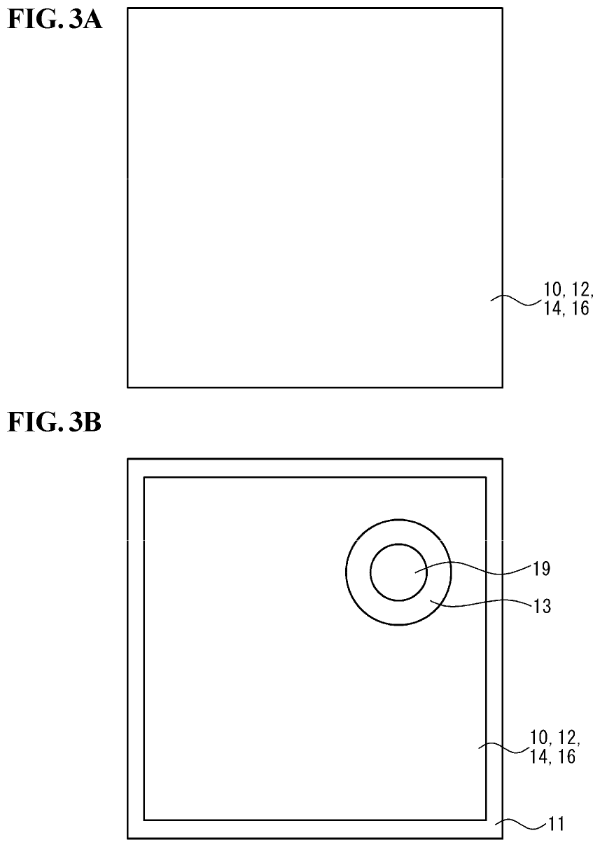

FIG. 3A to FIG. 9B are plan views illustrating a method of manufacturing the surface-emitting laser 100. As illustrated in FIG. 3A, the lower reflector layer 12, the active layer 14, and the upper reflector layer 16 are epitaxially grown in this order on the substrate 10 by, for example, a metal organic chemical vapor deposition (MOCVD) method or a molecular beam epitaxy (MBE) method. The lower reflector layer 12 includes an AlₓGa₁₋ₓAs layer (0.9×1.0) for forming the current confinement layer 22.

Ion implantation is performed to form the high-resistance region 20. For example, a photoresist having a thickness of 10 μm or more and 15 μm or less is applied by spin coating and is patterned by photolithography to protect a portion to be the mesa 19 by the photoresist. For example, ions such as protons (H⁺) are implanted to form the high-resistance region 20 illustrated in FIG. 1B. After the ion implantation, the photoresist is removed by an organic solvent and ashing with an oxygen plasma.

As illustrated in FIG. 3B, the mesa 19 is formed by dry etching of the high-resistance region 20 using, for example, inductively coupled plasma reactive ion etching (ICP-RIE) equipment. At this time, the groove 13 reaching the lower reflector layer 12 is formed in the high-resistance region 20, and a portion which is not to be etched is protected by a photoresist (not illustrated). As the etching gas, for example, a BCl₃ gas or a mixed gas of BCl₃ and Cl₂ is used. Examples of etching conditions are shown below.
BCl₃/Ar=30 sccm/70 sccm (or BCl₃/Cl₂/Ar=20 sccm/10 sccm/70 sccm)
ICP power: 50 W to 1000 W
Bias power: 50 W to 500 W
Wafer temperature: 25° C. or less

After the mesa 19 is formed, a portion of the upper reflector layer 16 is oxidized from the end side, for example, by heating to about 400° C. in a water vapor atmosphere to form the current confinement layer 22. The heating time is determined so that the current confinement layer 22 reaches a predetermined width and an unoxidized portion having a predetermined width remains inside the current confinement layer 22.

Further, the high-resistance region 20, the lower reflector layer 12, and a part of the substrate 10 are dry-etched to form the groove 11. The groove 11 is located between the plurality of substrates 10 in the wafer and overlaps the scribe lines. The groove 11 has a depth of 7 μm, for example, and extends through the high-resistance region 20 and the lower reflector layer 12. The groove 11 electrically separates the plurality of surface-emitting lasers 100 from each other. The surface of the substrate 10 exposed by etching serves as the bottom surface of the groove 11. At this time, portions not to be etched such as the mesa 19 and the groove 13 are covered with a photoresist (not illustrated). Examples of etching conditions are shown below.
BCl₃/Ar=30 sccm/70 sccm (or BCl₃/Cl₂/Ar=20 sccm/10 sccm/70 sccm)
ICP power: 50 W to 1000 W
Bias power: 50 W to 500 W
Wafer temperature: 25° C. or less

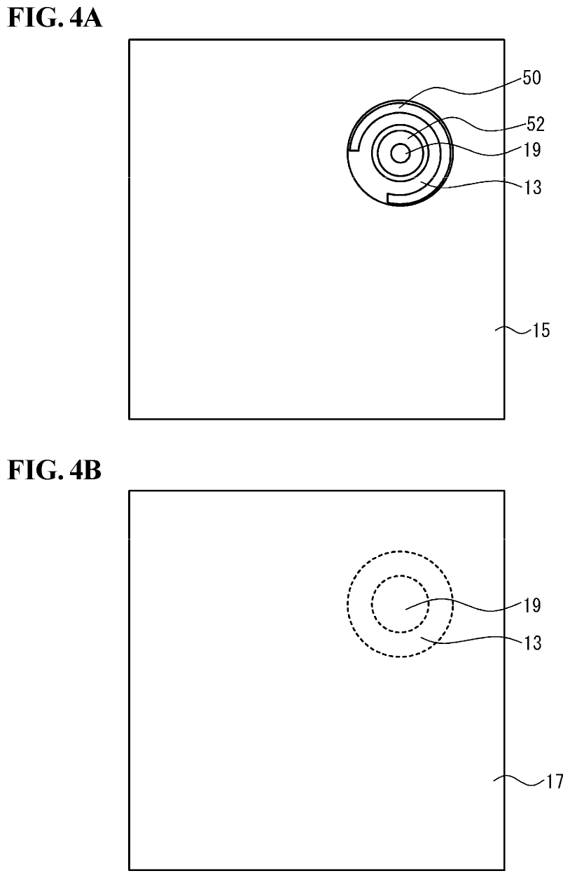

As illustrated in FIG. 4A, an insulating film 15 covering the wafer is formed by, for example, plasma-enhanced chemical vapor deposition (CVD). The insulating film 15 is, for example, a SiN film, and may further include a SiON film or a SiO₂ film. The material and thickness of the insulating film 15 are adjusted so that the insulating film 15 functions as a reflective film for light emitted from the surface-emitting laser 100. A resist pattern is formed on the insulating film 15, the electrode 50 (third electrode) is formed inside the groove 13 by a vacuum evaporation method, and the electrode 52 (fourth electrode) is formed on the mesa 19. The electrode 50 is, for example, a C-shaped electrode surrounding the mesa 19. After the electrodes 50 and 52 are formed, heat treatment is performed at a temperature of, e.g., about 400° C. for 1 minute, whereby ohmic contacts are made between the electrodes 50 and 52 and the semiconductor. The electrode 50 is electrically connected to the lower reflector layer 12, and the electrode 52 is electrically connected to the upper reflector layer 16.

As illustrated in FIG. 4B, the insulating film 17 (first insulating film) is formed on the insulating film 15 and the electrodes 50 and 52 by, for example, a plasma CVD method. The insulating film 17 is, for example, a SiON film or a SiO₂ film.

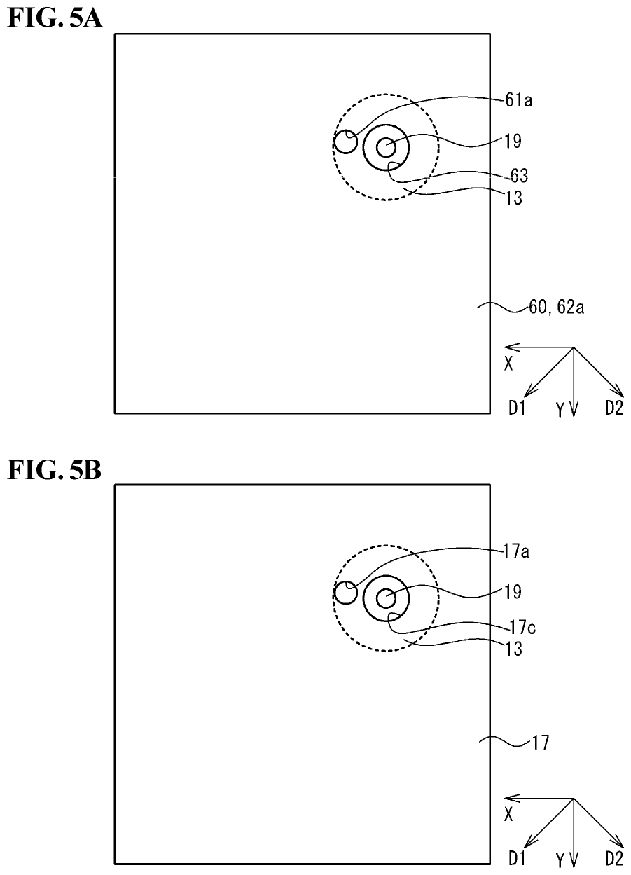

As illustrated in FIG. 5A, a resist 60 (third resist) is applied on the insulating film 17, and a photomask 62a (third mask) is provided on the resist 60. The photomask 62a has openings overlapping the groove 13 and the mesa 19. The resist 60 is patterned by photolithography using the photomask 62a to form openings 61a and 63. The opening 63 overlaps the mesa 19. The opening 61a overlaps the groove 13 and is located on the +X side with respect to the opening 63.

As illustrated in FIG. 5B, by etching the insulating film 17 using the pattern of the resist 60, an opening 17a (first opening) is formed in the insulating film 17 at a position overlapping with the opening 61a, and an opening 17c (second opening) is formed at a position overlapping with the opening 63. The opening 17c is located over the mesa 19, and the electrode 52 is exposed from the opening 17c. The opening 17a is located in the groove 13 on the +X side from the opening 17c, and the electrode 50 is exposed from the opening 17a. The resist 60 is removed.

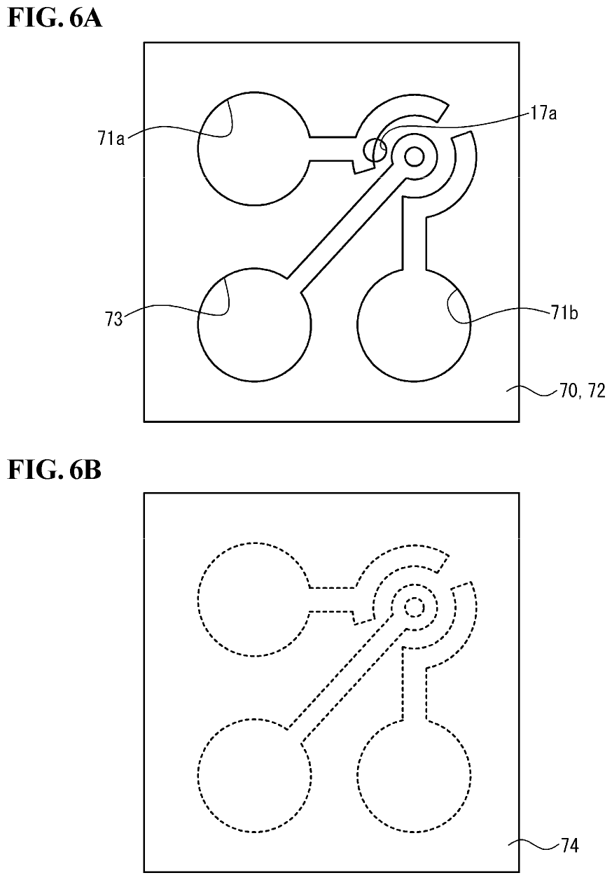

As illustrated in FIG. 6A, a resist 70 (first resist) is applied on the insulating film 17, and a photomask 72 (first mask) is provided on the resist 70. The resist 70 is patterned by photolithography using the photomask 72 to form openings 71a, 71b, and 73. The opening 71a is provided at a position corresponding to the pad 28a, the wiring 27, and the electrode 26 illustrated in FIG. 1A, and overlaps with the opening 17a of the insulating film 17. The opening 71b is provided at a position corresponding to the pad 28b, the wiring 27, and the electrode 26, and does not overlap with the opening 17a. The opening 73 is provided at a position corresponding to the pad 32, the wiring 31, and the electrode 30. As illustrated in FIG. 6B, for example, a TiW seed metal 74 (first metal layer) is formed over the entire surface of the wafer by sputtering or the like.

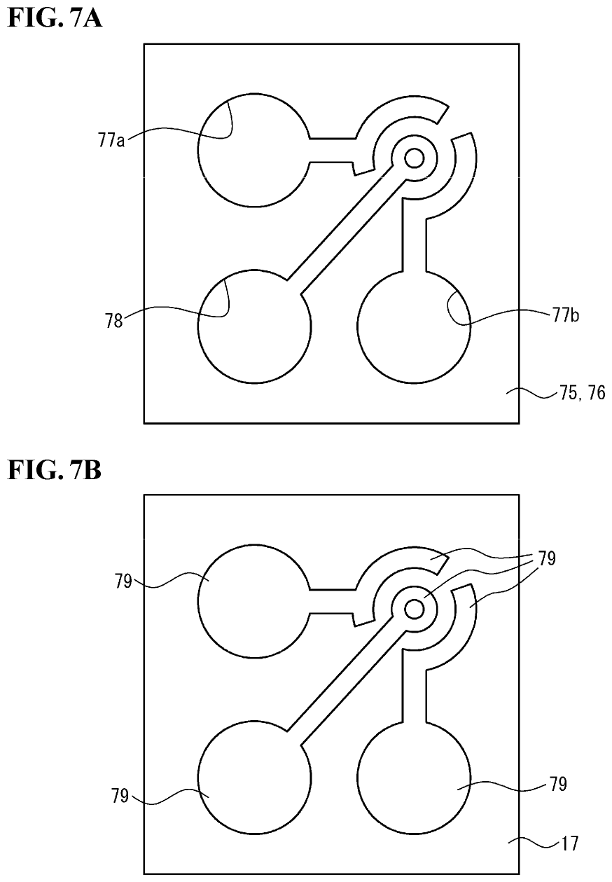

As illustrated in FIG. 7A, a resist 75 (second resist) is applied on the seed metal 74, and a photomask 76 (second mask) is provided on the resist 75. The photomask 76 has openings at positions where the pads 28a and 28b, the pad 32, the wiring 27 and 31, and the electrodes 26 and 30 are to be formed. The resist 75 is patterned by photolithography using the photomask 76 to form openings 77a, 77b, and 78. The opening 77a overlaps with the opening 71a illustrated in FIG. 6A, the opening 77b overlaps with the opening 71b, and the opening 78 overlaps with the opening 73. The seed metal 74 is exposed from each opening.

As illustrated in FIG. 7B, a plating process is performed to form a plating layer 79 (second metal layer) of gold (Au), for example. The plating layer 79 is formed on the seed metal 74 exposed from the openings 77a, 77b, and 78 of the resist 75. After the plating, the resist 75 is removed by a developer. The portion of the seed metal 74 exposed from the plating layer 79 and the resist 70 are removed by milling. The remaining stacks of the seed metal 74 and the plating layer 79 function as the electrodes 26 and 30, the wiring 27 and 31, and the pads 28a, 28b, and 32 illustrated in FIG. 1A.

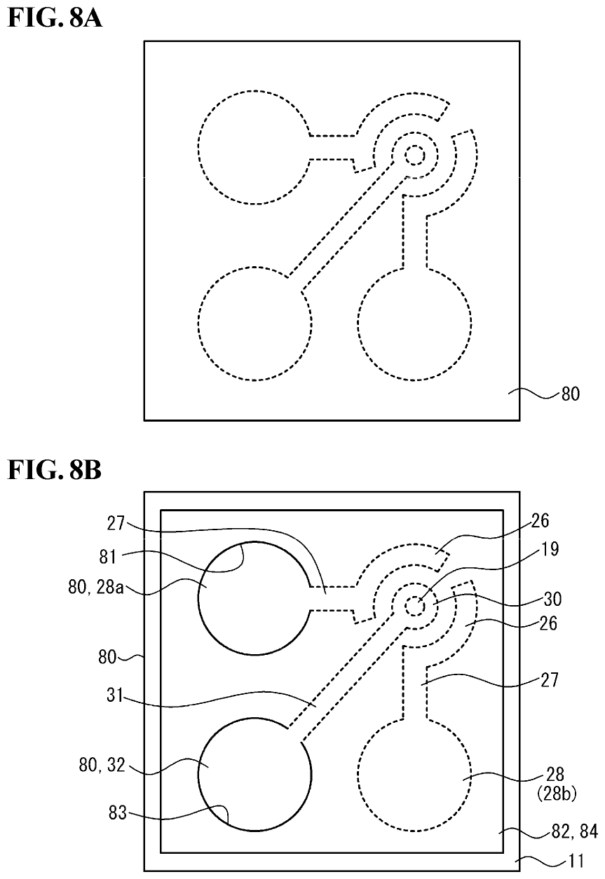

As illustrated in FIG. 8A, the insulating film 80 (second insulating film) is provided by, e.g., plasma CVD. The insulating film 80 is, for example, a passivation film formed of an insulator such as SiN or SiO₂, and covers the insulating film 17 and the plating layer 79.

As illustrated in FIG. 8B, a resist 82 (fourth resist) is applied on the insulating film 80, and a photomask 84 (fourth mask) is provided on the resist 82. The photomask 84 has openings over the pad 28a and the pad 32. The photomask 84 does not overlap the groove 11 of the substrate 10. Openings 81 and 83 are formed in the resist 82 by photolithography using the photomask 84. The portion of the insulating film 80 that overlaps with the pad 28a is exposed from the opening 81, and the portion that overlaps with the pad 32 is exposed from the opening 83. In addition, a portion of the insulating film 80 that overlaps with the groove 11 is exposed from the resist 82.

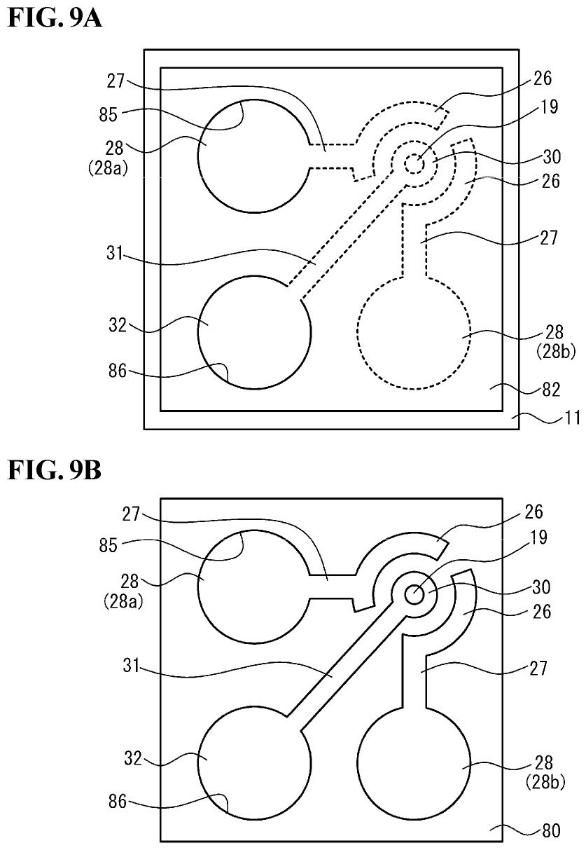

As illustrated in FIG. 9A, the insulating film 80 is etched by using the resist 82. An opening 85 (third opening) and an opening 86 (fourth opening) are formed in the insulating film 80 by etching, and the portion over the groove 11 is removed. The pad 28a is exposed from the opening 85, the pad 32 is exposed from the opening 86, and the groove 11 is also exposed from the insulating film 80. The pad 28b, the mesa 19, and the wiring 27 and 31 are covered with the insulating film 80. The resist 82 is removed. The back face of the substrate 10 is polished by using, for example, a back grinder or a lapping apparatus, and the wafer is cut along the scribe lines by a dicer, thereby forming a plurality of surface-emitting lasers 100 from the wafer.

In the surface-emitting laser 100 manufactured by the above process, the pad 28a is electrically connected to the electrode 50 and the mesa 19 through the opening 17a illustrated in FIG. 5B. Accordingly, when the surface-emitting laser 100 is used in the electronic device 112 illustrated in FIG. 2B, the pad 28a and the pad 42b can be electrically connected to each other. On the other hand, since the pad 28b is not electrically connected to the electrode 50 and the mesa 19, it is difficult to use the surface-emitting laser 100 in the electronic device 110 illustrated in FIG. 2A.

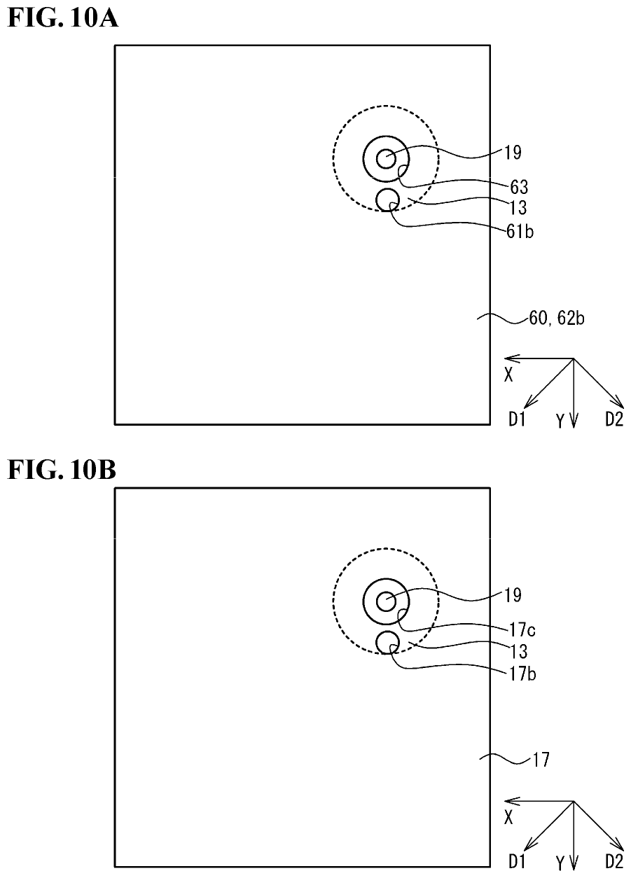

The surface-emitting laser 100 usable in the electronic device 110 illustrated in FIG. 2A can also be manufactured. FIG. 10A and FIG. 10B are plan views illustrating a method of manufacturing the surface-emitting laser 100. The steps of FIG. 3A to FIG. 4B and FIG. 6A to FIG. 9B are common, and the steps illustrated in FIG. 10A and FIG. 10B are performed instead of the steps shown in FIG. 5A and FIG. 5B.

A photomask 62b illustrated in FIG. 10A has an opening at a position different from that of the photomask 62a illustrated in FIG. 5A. Openings 61b and 63 are formed in the resist 60 by photolithography using the photomask 62b. The opening 61b is positioned on the +Y side with reference to the opening 63. As illustrated in FIG. 10B, the insulating film 17 is etched by using the pattern of the resist 60, whereby the opening 17c overlapping the opening 63 and an opening 17b overlapping the opening 61b are formed in the insulating film 17. The opening 17b is located in the groove 13 on the +Y side from the opening 17c, and the electrode 50 is exposed from the opening 17b.

In the surface-emitting laser 100 manufactured by the above process, the pad 28b is electrically connected to the electrode 50 and the mesa 19 through the opening 17b. Therefore, when the surface-emitting laser 100 is used in the electronic device 110 illustrated in FIG. 2A, the pad 28b and the pad 42b can be electrically connected to each other.

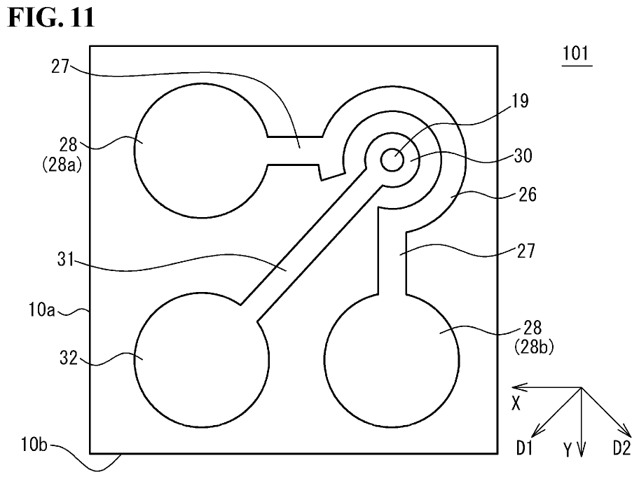

FIG. 11 is a plan view illustrating a surface-emitting laser 101 according to a modification of the first embodiment. The electrode 26 forms a C-shape, and the pads 28a and 28b are electrically connected to the electrode 50 and the mesa 19 through the electrode 26. However, parasitic capacitance is generated between the pads 28a and 28b and the conductive semiconductor layers, such as the lower reflector layer 12. Since the two pads 28a and 28b are electrically connected to each other, the parasitic capacitance increases, and modulation at high speed becomes difficult. Therefore, it is preferable to connect one of the pads 28a and 28b to the mesa 19 and use the other as a floating electrode in accordance with the arrangement of the pads on the printed circuit board 40 on which the surface-emitting laser 101 is to be mounted.

### Comparative Examples

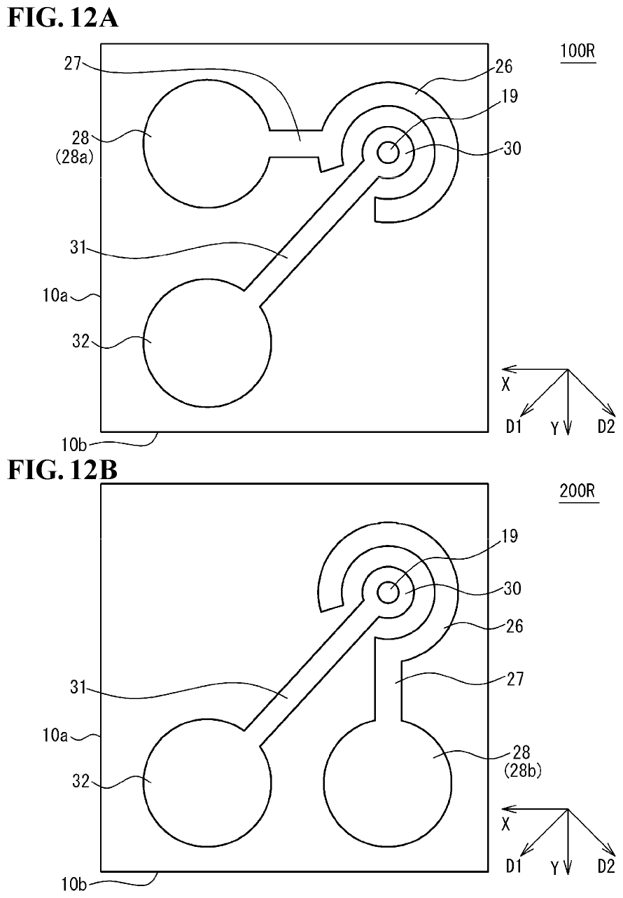

Next, comparative examples will be described. FIG. 12A is a plan view illustrating a surface-emitting laser 100R according to Comparative Example 1, and FIG. 12B is a plan view illustrating a surface-emitting laser 200R according to Comparative Example 2. As illustrated in FIG. 12A, the surface-emitting laser 100R has the pad 28a and the pad 32, and does not have the pad 28b. As illustrated in FIG. 12B, the surface-emitting laser 200R has the pad 28b and the pad 32, and does not have the pad 28a.

The surface-emitting laser 100R can be mounted on the printed circuit board 40 illustrated in FIG. 2B. However, it is difficult to mount the surface-emitting laser 100R on the printed circuit board 40 of FIG. 2A such that the pad 28a faces the pad 42b and the pad 32 faces the pad 42a. On the other hand, the surface-emitting laser 200R can be mounted on the printed circuit board 40 illustrated in FIG. 2A. However, it is difficult to mount the surface-emitting laser 200R on the printed circuit board 40 of FIG. 2B such that the pad 28b faces the pad 42b and the pad 32 faces the pad 42a. However, it is difficult to mount the surface-emitting laser 200R on the printed circuit board 40 of FIG. 2B such that the pad 28b faces the pad 42b and the pad 32 faces the pad 42a.

Therefore, both the surface-emitting laser 100R and the surface-emitting laser 200R are manufactured in accordance with the arrangement of the printed circuit board 40. However, different photomasks are used for the surface-emitting lasers 100R and 200R for each of the steps corresponding to FIG. 5A, FIG. 6A, FIG. 7A, and FIG. 8B. Therefore, for example, eight types of photomasks are used. Therefore, cost of the manufacturing method increases.

In contrast, according to the first embodiment, the pad 28a and the pad 32 are arranged in the Y-axis direction, and the pad 28b and the pad 32 are arranged in the X-axis direction. Therefore, the arrangement of the pads can be changed by changing the orientation of the surface-emitting laser 100. Since it is not necessary to manufacture a plurality of types of surface-emitting lasers having different pad arrangements, cost can be reduced.

More specifically, in each of FIG. 6A, FIG. 7A, and FIG. 8B, one type of photomask is sufficient. In FIG. 8B, the photomask 84 having openings corresponding to two pads is used. By rotating the photomask 84, an opening can be formed in a portion of the resist 82 corresponding to one of the pads 28a and 28b. Two types of photomasks are used to produce the examples of FIG. 5A and FIG. 10A. Therefore, for example, five types of photomasks may be used, and the number of types of photomasks can be reduced as compared with the comparative examples. Thus, the cost of manufacturing can be reduced.

As illustrated in FIG. 1A, the substrate 10 has a rectangular shape, and the mesa 19 and the pads 28a, 28b, and 32 are arranged at the four corners of the substrate 10. The pad 28a and the pad 32 are arranged along the side 10a of the substrate 10, and the pad 28b and the pad 32 are arranged along the side 10b. The surface-emitting laser 100 can be mounted by rotating the surface-emitting laser 100 by 90 degrees such that one of the sides 10a and 10b faces the pads 42a and 42b of the printed circuit board 40.

For example, in the example of FIG. 2A, the side 10b of the surface-emitting laser 100 is opposed to the pads 42a and 42b. As a result, the pad 42b and the pad 28b are opposed to each other, and the pad 42a and the pad 32 are opposed to each other. In the example of FIG. 2B, the side 10a of the surface-emitting laser 100 is opposed to the pads 42a and 42b. As a result, the pad 42b and the pad 28a are opposed to each other, and the pad 42a and the pad 32 are opposed to each other. Therefore, wire bonding can be performed between the pads without crossing the bonding wires 43a and 43b. In addition, a plurality of types of surface-emitting lasers 100 corresponding to the arrangement of the pads of the printed circuit board 40 can be manufactured at low cost. Therefore, the cost of the electronic devices 110 and 112 can be reduced.

As in the example of FIG. 11, both of the two pads 28a and 28b may be connected to the mesa 19. However, it is preferable that one of the two pads 28a and 28b be electrically connected to the mesa 19 and the other be not electrically connected to the mesa 19. This makes it possible to suppress an increase in the parasitic capacitance and to perform modulation at high speed.

The mesa 19 includes the lower reflector layer 12, the active layer 14, and the upper reflector layer 16. One of the pads 28a and 28b is connected to the lower reflector layer 12 through the wiring 27 and the electrode 26 illustrated in FIG. 1A and the electrode 50 illustrated in FIG. 4A. The pad 32 is connected to the upper reflector layer 16 through the wiring 31 and the electrode 30 illustrated in FIG. 1A and the electrode 52 illustrated in FIG. 4A. By inputting an electric signal from the pads, light can be emitted from the mesa 19. Since the other of the pads 28a and 28b is not connected to the lower reflector layer 12, an increase in parasitic capacitance can be suppressed.

The openings 61a and 63 are formed in the resist 60 using the photomask 62a as illustrated in FIG. 5A, and the openings 17a and 17c are formed in the insulating film 17 as illustrated in FIG. 5B. The pad 28a is electrically connected to the electrode 50 and the lower reflector layer 12 through the opening 17a, and the pad 28b is not connected thereto. Therefore, an increase in the parasitic capacitance can be suppressed. As illustrated in FIG. 10A and FIG. 10B, if the photomask 62b having an opening at a different position is used, the pad 28b is connected to the lower reflector layer 12, and the pad 28a is not connected thereto. Even if these examples are included, five types of photomasks may be used, and the number of types of photomasks is smaller than the eight types of Comparative Examples 1 and 2. Therefore, the cost can be reduced.

Of the pads 28a and 28b, the pad connected to the electrode 50 is used for a characteristic test or the like, and is contacted by a probe. Since the probe does not contact the other of the pads 28a and 28b, no probe mark is likely to be formed. For example, in an appearance inspection by image recognition or the like, a simple and highly accurate inspection is possible by using a pad without a probe mark as a reference. In addition, it is preferable to use a pad without a probe mark in alignment by image recognition.

The substrate 10 may have a shape other than a rectangular shape. The pads 28a, 28b, and 32 and the mesa 19 may be located at locations other than the four corners. In the example of FIG. 1A, the direction in which the pad 28a and the pad 32 are arranged is orthogonal to the direction in which the pad 28b and the pad 32 are arranged, but these directions may intersect each other at any angle. The first embodiment may be applied to a light-receiving element rather than to a light-emitting element.

### Second Embodiment

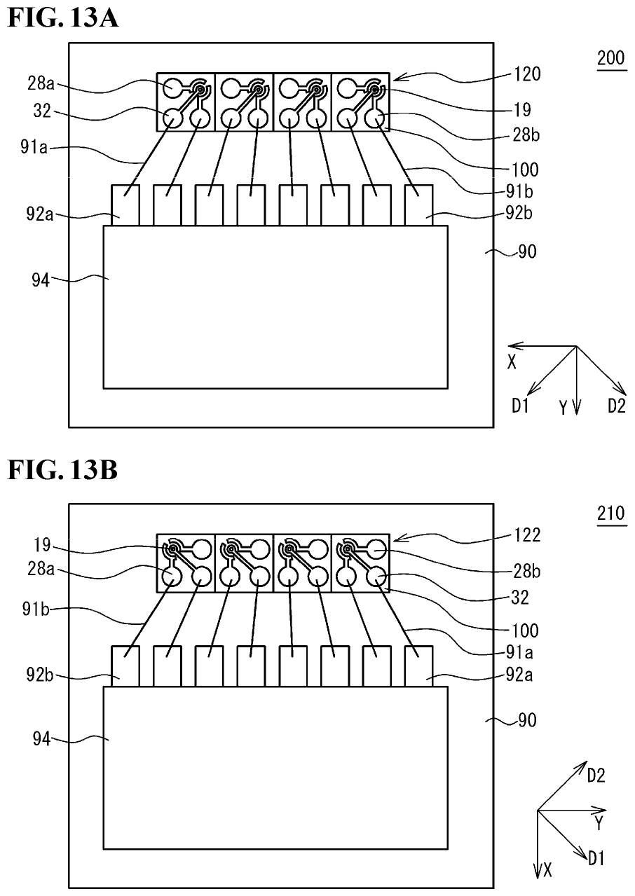

In a second embodiment, an array chip including a plurality of surface-emitting lasers 100 is used. FIG. 13A and FIG. 13B are plan views illustrating electronic devices according to the second embodiment. An electronic device 200 illustrated in FIG. 13A includes a printed circuit board 90, pads 92a and 92b, a control integrated circuit (IC) 94, and an array chip 120. The plurality of pads 92a and 92b are provided on the surface of the printed circuit board 90, and the control IC 94 and the array chip 120 are mounted on the surface of the printed circuit board 90. The printed circuit board 90 may be provided with a lens array and a mirror on which light emitted from the array chip 120 is incident, and a housing to cover the control IC 94 and the array chip 120.

The pads 92a are anode electrodes, and the pads 92b are cathode electrodes. The pads 92b and the pads 92a are alternately arranged in the X-axis direction in order from the −X side to the +X side. The pads 92b and the pads 92a are alternately arranged in the X-axis direction in order from the −X side to the +X side.

The pads 92b and the pads 92a are alternately arranged in the X-axis direction in order from the −X side to the +X side. The plurality of surface-emitting lasers 100 are connected in a line in the X-axis direction. In the array chip 120, the mesa 19 and the pad 28b of each surface-emitting laser 100 are adjacent to the pads 28a and 32 of the adjacent surface-emitting laser 100. The pads 28b and 32 are alternately arranged in the X-axis direction in order from the −X side to the +X side, and face the control IC 94 and the pads 92a and 92b in the Y-axis direction.

The pads 32 of the array chip 120 and the pads 92a of the printed circuit board 90 are electrically connected by bonding wires 91a. The pads 28b of the array chip 120 and the pads 92b of the printed circuit board 90 are electrically connected by bonding wires 91b. In the electronic device 200, the pads 32, which are anode electrodes, are opposed to the pads 92a, and the pads 28b, which are cathode electrodes, are opposed to the pad 92b. As a result, the pads can be connected to each other without crossing the bonding wires 91a and 91b.

An electronic device 210 shown in FIG. 13B includes the printed circuit board 90, the pads 92a and 92b, the control IC 94, and an array chip 122. The order of arrangement of the pads 92a and 92b on the printed circuit board 90 is opposite to that of the electronic device 200. The pads 92a and 92b are alternately arranged in the Y-axis direction in order from the +Y side to the −Y side.

The array chip 122 includes a plurality of surface-emitting lasers 100. The surface-emitting lasers 100 in the array chip 122 are rotated to the left by 90° compared to the surface-emitting lasers 100 in the array chip 120. That is, the mesa 19 and the pad 28a of each surface-emitting laser 100 are adjacent to the pads 28b and 32 of the adjacent surface-emitting laser 100. The pads 32 and 28a are alternately arranged in the Y-axis direction in order from the +Y side to the −Y side, and face the control IC 94 and the pads 92a and 92b in the X-axis direction. The pads 32 of the array chip 122 and the pads 92a of the printed circuit board 90 are electrically connected by the bonding wires 91a. The pads 32 of the array chip 122 and the pads 92a of the printed circuit board 90 are electrically connected by the bonding wires 91a. The pads 28a of the array chip 122 and the pads 92b of the printed circuit board 90 are electrically connected by the bonding wires 91b. The pads can be connected to each other without crossing the bonding wires 91a and 91b.

According to the second embodiment, a plurality of types of array chips corresponding to the arrangement of the pads of the printed circuit board 90 can be manufactured at low cost. Therefore, the cost of the electronic devices 200 and 210 can be reduced. In addition, since interference between bonding wires is suppressed, wire bonding is facilitated and cost can be reduced.

The array chips 120 and 122 can be obtained by cutting the wafer so that a plurality of surface-emitting lasers 100 are connected after the step shown in FIG. 9A. The number of the surface-emitting lasers 100 included in the array chips 120 and 122 is plural, and may be less than four, or may be four or more.

Although the embodiments of the present invention have been described above in detail, the present invention is not limited to the specific embodiments, and various modifications and variations are possible within the scope of the gist of the present invention described in the claims.

What is claimed is:

1. A surface-emitting laser comprising:
a light-emitting portion provided on a substrate; and
two first electrodes and a second electrode provided over the substrate,
wherein
at least one of the two first electrodes and the second electrode are electrically connected to the light-emitting portion,
the at least one of the two first electrodes is one of a cathode electrode and an anode electrode,
the second electrode is the other of the cathode electrode and the anode electrode,
one of the two first electrodes and the second electrode are arranged in a first direction, and
the other of the two first electrodes and the second electrode are arranged in a second direction intersecting the first direction.

2. The surface-emitting laser according to claim 1, wherein
the substrate has a rectangular shape,
the two first electrodes are opposed to two of four corners of the substrate,
the second electrode is opposed to one of the four corners,
one of the two first electrodes and the second electrode are arranged along a first side of the substrate, and
the other of the two first electrodes and the second electrode are arranged along a second side of the substrate adjacent to the first side.

3. The surface-emitting laser according to claim 1, wherein one of the two first electrodes is electrically connected to the light-emitting portion, and the other is not connected to the light-emitting portion.

4. The surface-emitting laser according to claim 1, wherein
the light-emitting portion includes a lower reflector layer provided on the substrate,
an active layer provided on the lower reflector layer, and
an upper reflector layer provided on the active layer,
the first electrodes and the second electrode are located above the upper reflector layer,
the at least one of the two first electrodes is electrically connected to the lower reflector layer, and
the second electrode is electrically connected to the upper reflector layer.

5. An electronic device comprising:
a mounting substrate; and
a surface-emitting laser mounted on the mounting substrate,
the surface-emitting laser having a light-emitting portion provided on a substrate and two first electrodes and a second electrode provided over the substrate,
at least one of the two first electrodes and the second electrode being electrically connected to the light-emitting portion,
the at least one of the two first electrodes being one of a cathode electrode and an anode electrode,
the second electrode being the other of the cathode electrode and the anode electrode,
one of the two first electrodes and the second electrode being arranged in a first direction,
the other of the two first electrodes and the second electrode being arranged in a second direction intersecting the first direction, the mounting substrate having a first pad and a second pad,
the first pad being opposed to one of the two first electrodes and being electrically connected to the one of the two first electrodes using a first bonding wire and not electrically connected to the other of the two first electrodes, and
the second pad being opposed to the second electrode and being electrically connected to the second electrode using a second bonding wire.

6. A method of manufacturing a surface-emitting laser, comprising the steps of:
forming a light-emitting portion on a substrate; and
forming two first electrodes and a second electrode over the substrate,
wherein
at least one of the two first electrodes and the second electrode are electrically connected to the light-emitting portion,
the at least one of the two first electrodes is one of a cathode electrode and an anode electrode,
the second electrode is the other of the cathode electrode and the anode electrode,
one of the two first electrodes and the second electrode are arranged in a first direction, and
the other of the two first electrodes and the second electrode are arranged in a second direction intersecting the first direction.

7. The method of manufacturing a surface-emitting laser according to claim 6,
wherein
the first electrodes and the second electrode include a first metal layer and a second metal layer, and
the step of forming the first electrodes and the second electrode includes the substeps of:
forming a first resist and a first mask in order over the substrate and patterning the first resist using the first mask;
forming the first metal layer over the first resist;
forming a second resist and a second mask in order on the first metal layer and patterning the second resist using the second mask; and
forming the second metal layer on the second resist and the first metal layer.

8. The method of manufacturing a surface-emitting laser according to claim 6, further comprising the steps of:
forming a third electrode and a fourth electrode electrically connected to the light-emitting portion;
forming a first insulating film over the substrate, the third electrode, and the fourth electrode;
forming a third resist and a third mask on the first insulating film in order and patterning the third resist using the third mask; and
etching the first insulating film using the third resist to form a first opening through which the third electrode is exposed and a second opening through which the fourth electrode is exposed in the first insulating film,
wherein
the step of forming the first electrodes and the second electrode is performed after the step of forming the first opening and the second opening in the first insulating film,
one of the two first electrodes is electrically connected to the third electrode through the first opening,
the other of the two first electrodes is not electrically connected to the third electrode, and
the second electrode is electrically connected to the fourth electrode through the second opening.

9. The method of manufacturing a surface-emitting laser according to claim 6, further comprising the steps of:
forming a second insulating film over the substrate, the first electrodes, and the second electrode;
forming a fourth resist and a fourth mask in order on the second insulating film and patterning the fourth resist using the fourth mask; and
etching the second insulating film using the fourth resist to form a third opening through which one of the first electrodes is exposed and a fourth opening through which the second electrode is exposed in the second insulating film.
